(19) United States
(12) Patent Application Publication
(10) Pub. No.: US 2022/0330454 A1
(43) Pub. Date: Oct. 13, 2022

(54) METHODS AND APPARATUS TO REMOVE DUST WITH A REVERSE FAN PULSE

(71) Applicant: Intel Corporation, Santa Clara, CA (US)

(72) Inventors: Bijendra Singh, Bangalore (IN); Govindaraj G, Bangalore (IN)

(21) Appl. No.: 17/853,239

(22) Filed: Jun. 29, 2022

(51) Int. Cl. H05K 7/20; F01P 1/06

(52) U.S. Cl. CPC H05K 7/20172; H05K 7/20209; F01P 1/06; F01P 2023/08; F01P 2025/08

(57) ABSTRACT

Methods, apparatus, systems, and articles of manufacture are disclosed to remove dust from an electronic device. An example apparatus includes a fan to rotate in a first direction in a first mode of operation of the electronic device, the first mode of operation corresponding to user operation of the electronic device, at least one memory, machine readable instructions, and processor circuitry to at least one of instantiate or execute the machine readable instructions to determine an operation time of the fan in the first mode of operation, and cause the fan to operate in a second mode of operation based on the operation time exceeding a threshold time, and, wherein in the second mode, pulsed power is applied to the fan to rotate the fan in a second direction opposite the first direction.

### FIELD OF THE DISCLOSURE

This disclosure relates generally to electronic devices and, more particularly, to methods and apparatus to remove dust with a reverse fan pulse.

### BACKGROUND

During operation of an electronic user device (e.g., a laptop, a desktop, a tablet), hardware components of the device, such as a processor, a graphics card, and/or a battery, generate heat. Electronic user devices include one or more fans to promote airflow to cool the device during use and prevent overheating of the hardware components.

### BRIEF DESCRIPTION OF THE DRAWINGS

FIG. 1A illustrates an example system constructed in accordance with teachings of this disclosure that includes an example user device implemented as a laptop.

FIG. 1B illustrates the example system constructed in accordance with teachings of this disclosure that includes the example user device.

FIG. 2 is a block diagram of example reverse pulse circuitry of the user device of FIG. 1.

FIG. 3 is an illustration of example fan rotation schemes that can be implemented by the example reverse pulse circuitry of FIG. 2.

FIG. 4 is an illustration of a speed of example fan rotation schemes that can be implemented by the example reverse pulse circuitry of FIG. 2.

FIG. 5 is an illustration of a loudness comparison of example fan rotation schemes implemented by the example reverse pulse circuitry of FIG. 2.

FIG. 6 is an illustration of a dust accumulation comparison of example fan rotation schemes implemented by the example reverse pulse circuitry of FIG. 2.

FIG. 7 is an illustration of an example system performance comparison of example fan rotation schemes implemented by the example reverse pulse circuitry of FIG. 2.

FIG. 8 is a pseudocode representative of example machine readable instructions and/or operations that may be executed by example processor circuitry to implement the reverse pulse circuitry of FIG. 2 to place the fan in maintenance mode.

FIG. 9 is a flowchart representative of example machine readable instructions and/or example operations that may be executed by example processor circuitry to implement the reverse pulse circuitry of FIG. 2 to place the fan in maintenance mode.

FIG. 10 is a flowchart representative of example machine readable instructions and/or example operations that may be executed by example processor circuitry to implement the reverse pulse circuitry of FIG. 2 to determine if the conditions are satisfied to place the fan in maintenance mode.

FIG. 11 flowchart representative of example machine readable instructions and/or example operations that may be executed by example processor circuitry to implement the reverse pulse circuitry of FIG. 2 to apply pulsed power to the fan.

FIG. 12 is a block diagram of an example processing platform including processor circuitry structured to execute the example machine readable instructions and/or the example operations of FIGS. 9-11 to implement the reverse pulse circuitry of FIG. 2.

FIG. 13 is a block diagram of an example implementation of the processor circuitry of FIG. 12.

FIG. 14 is a block diagram of another example implementation of the processor circuitry of FIG. 12.

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description. As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

During operation of an electronic user device (e.g., a laptop, a tablet, a desktop computer, etc.), hardware components disposed in a body or housing of the device, such as a processor, graphics card, and/or battery, generate heat. To prevent overheating of the hardware components, damage to the device, and/or discomfort to the user of the device when the user touches or places one or more portions of the user's body proximate to a skin of the device and/or components of the device accessible via the exterior surface of the housing such as a touchpad, the user device includes one or more fans to exhaust hot air generated within the body of the device and cool the device.

Some known electronic user devices are configured with one or more thermal constraints to control the temperature of the hardware components of the user device and/or of the skin of the device. In known user devices, operation of the fan(s) of the user device and/or management of power consumed by the device are controlled based on the thermal constraint(s). For instance, if a temperature of a hardware component of the device is approaching a maximum temperature as defined by the thermal constraint for the component, rotational speed(s) (e.g., revolutions per minute (RPMs)) of the fan(s) can be increased to exhaust hot air and reduce a temperature of the component. Additionally or alternatively, power consumption by one or more components of the device (e.g., the graphics card) may be reduced to reduce the amount of heat generated by the component and, thus, the device.

In some known user devices, the thermal constraint(s) correspond to a temperature of the skin of the device should not exceed, for instance, 45° C., to prevent user discomfort when the user is physically touching the device (e.g., typing on a keyboard of a laptop, scrolling on a touchscreen, etc.). Temperature of the skin of the device can be controlled by controlling power consumption of the hardware component(s) disposed within the device body to manage the amount of heat generated by the component(s) transferred to the skin of the device. However, such thermal constraint(s) can affect performance of the user device. For instance, some known user devices can operate in a high performance mode, or a mode that favors increased processing speeds over energy conservation (e.g., a mode in which processing speeds remain high for the duration that the device is in use, the screen remains brightly lit, and other hardware components do not enter power-saving mode when those components are not in use). The processor consumes increased power to accommodate the increased processing speeds associated with the high performance mode and, thus, the amount of heat generated by the processor is increased. As a result, a temperature of the skin of the user device can increase due to the increased amount of heat generated within the device housing. In some known devices, the processor may operate at lower performance speeds to consume less power and, thus, prevent the skin of the device from exceeding the maximum skin temperature defined by the thermal constraint. Thus, in some known devices, processing performance is sacrificed in view of thermal constraint(s). In some examples, the high performance mode is a gaming mode or a video editing mode.

Increased fan speeds can be used to facilitate cooling of hardware component(s) of a device to enable the component(s) to operate in, for instance, a high performance mode without exceeding the thermal constraint(s) for the hardware competent(s) and/or the device skin. However, operation of the fan(s) at higher speeds increases audible acoustic noise generated by the fan(s). To mitigate the acoustic noise, in some known user devices, the fan speed(s) and, thus, the amount of cooling that is provided by the fan(s), are restricted to avoid generating fan noise levels over certain decibels. Some known devices define fan noise constraints that set, for instance, a maximum noise level of 35 dBA during operation of the fan(s). As a result of the restricted fan speed(s), performance of the device may be limited to enable the fan(s) to cool the user device within the constraints of the fan speed(s).

In some instances, cooling capabilities of the fan(s) of the device degrade over time due to dust accumulating on the fan(s) and/or a heat sink of the device. Some known user devices direct the fan(s) to reverse airflow direction (e.g., as compared to the default airflow direction to exhaust hot air from the device) to facilitate heat sink and fan shroud cleaning, which helps to remove dust from the airflow path and maintain device performance over time. However, operation of the fan(s) in the reverse direction increases noise generated by the fan(s), which can negatively impact the user's experience with the device.

Disclosed herein are example user devices that provide for reduction and/or removal of dust from the airflow path of the user devices. The disclosed examples employ fan(s) that reverse airflow direction by applying pulsed power to the fan(s) to rotate the fan(s) in a second direction opposite a first direction corresponding to user operation of the fan(s).

As used herein, pulsed power refers to pulse width modulated power. In pulse width modulation, an electrical signal (e.g., electrical power) is sent to a device via a pulse. The pulse provides electrical power to the device for the duration of the pulse. After the pulse, there is a period of time during which electrical power is not sent to the device. After the period of time that electrical power is not sent to the device elapses, a subsequent pulse of power is sent to the device. By applying pulsed power, the amount of electrical power consumed by the fan is reduced, as well as the rotational speed of the fan(s). In addition, applying pulsed power to the fan of an electrical device reduces the noise (e.g., dB, loudness) that is produced during the usage of the fan(s).

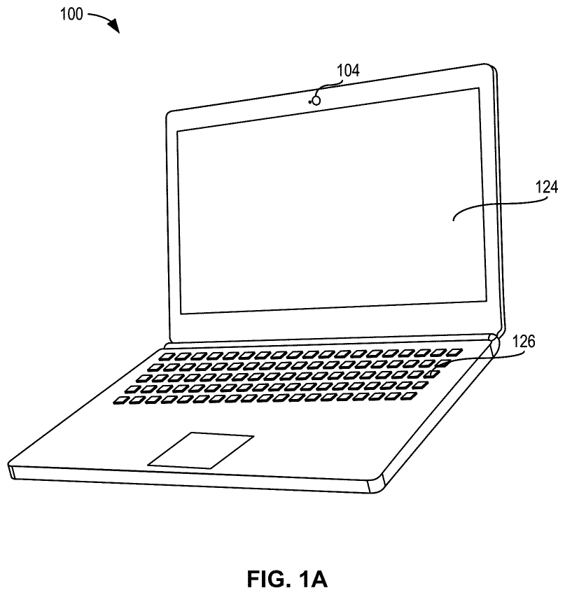

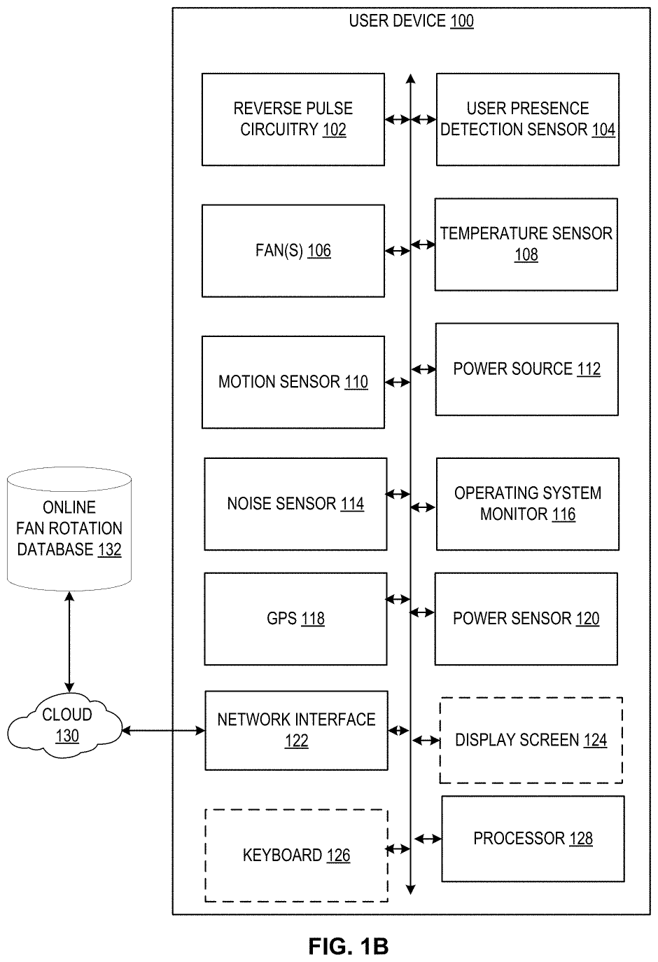

FIG. 1A illustrates an example system constructed in accordance with teachings of this disclosure that includes an example user device 100 implemented as a laptop. FIG. 1B illustrates the example system constructed in accordance with teachings of this disclosure that includes the example user device 100. The user device 100 may be, for example, a personal computing (PC) device such as a laptop, a desktop, an electronic tablet, a hybrid or convertible PC, etc. The user device 100 includes example reverse pulse circuitry 102, an example user presence detection sensor 104, example fan(s) 106, an example temperature sensor 108, an example motion sensor 110, an example power source 112, an example noise sensor 114, an example operating system monitor 116, an example Global Positioning System (GPS) 118, an example power sensor 120, an example network interface 122, example display screen 124, example keyboard 126, and an example processor 128. In some examples, the display screen 124 and/or the keyboard 126 are optional components of the user device 100. In the example of FIG. 1, the network interface 122 is in communication with an example cloud 130 (e.g., the Internet).

The user device 100 includes fan(s) 106 to provide means for cooling and/or regulating the temperature of the hardware component(s) (e.g., the processor 128) of the user device 100 in response to temperature data measured by the temperature sensor 108. In some examples, the fan(s) 106 are relatively loud (e.g., above a decibel threshold) when the fan(s) 106 are in operation. Disclosed examples include at least two fan operation modes. For example, in a first fan operation mode, the fan operates to cool the user device 100. A hardware-intensive or computationally intensive task (e.g., gaming, video editing, a high usage task) that uses more processing power and generates more heat, may operate the fan(s) 106 for longer durations and/or at higher revolutions per minute than a hardware-light or less computationally intensive task (e.g., browsing a webpage, editing a document, a low usage task). Thus, the user device 100 uses the first fan operation mode to cool the user device 100 during both hardware-intensive tasks and hardware-light tasks. In operation, a second mode the fan operates to remove dust and/or debris from the user device 100. During normal operation of the fan(s) 106, the airflow that cools the internal circuitry of the user device 100 (e.g., the air that flows during the first fan operation mode) may include dust particles. The dust particles that travel with the air can, over time, clog a passageway (e.g., an airflow path through and/or over a heatsink) of the user device 100.

The example user presence detection sensor 104 is implemented to determine if a user of the user device 100 is in proximity of the user device 100. For example, the user presence detection sensor 104 may be implemented by a camera that captures images of users in front of the user device 100. The reverse pulse circuitry 102 utilizes a determination from the user presence detection sensor 104 to determine that the fan(s) 106 are to operate in the second mode of operation (e.g., maintenance mode, cleaning mode, second mode). The user presence detection sensor 104 determines if, based on the proximity of the user to the user device 100, the user will hear the noise generated by the fan(s) 106. For example, if the user is not present (e.g., in front of the user device 100), the reverse pulse circuitry 102 may apply the pulsed power to the fan(s) 106 so that the fan(s) 106 rotate in the reverse direction to remove dust from the user device 100. In some examples, the reverse pulse circuitry 102 activates the fan(s) 106 despite a user being present.

The temperature sensor 108 determines the temperature of the internal components of the user device 100. If the measured temperature of the internal components of the user device 100 is greater than a threshold temperature (e.g., 45 degrees Celsius), the reverse pulse circuitry 102 is to control the fan(s) 106 to cool the internal temperature of the internal components. In some examples, the fan(s) 106 are operated in the first mode (e.g., the cooling mode to reduce the temperature of the internal components). For example, in response to a first temperature measurement from the temperature sensor, the reverse pulse circuitry 102 is to cause the fan to enter the first mode to cool the user device 100. In response to a second temperature measurement that is less than the first temperature measurement, the reverse pulse circuitry 102 can cause the fan to enter the second mode, for example.

In some examples, the motion sensor 110 is implemented by a gyroscope. The motion sensor 110 is to determine when the user device 100 is in motion (e.g., when a user carries or moves the user device 100). In some examples, the reverse pulse circuitry 102 may determine to not apply pulsed power to the fan(s) 106 when the user device 100 is in motion. For example, when a user moves the user device 100, the user may cover (e.g., block) a fan grating thereby preventing air from flowing through the fan grating to the internal components of the user device 100. In some examples, the motion sensor 110 indicates to the reverse pulse circuitry 102 that the user device 100 is stationary, and based on the stationary indication, the reverse pulse circuitry 102 determines to apply pulsed power to the fan(s) 106.

The power source 112 (e.g., a battery) of the illustrated example is to provide electrical power to the user device 100. The electrical power heats the internal components of the user device 100. The internal components (e.g., processor 128, video graphics card, etc.) generate heat during operation of the user device 100.

In some examples, the noise sensor 114 is implemented by one or more microphone(s) to detect sounds in an environment in which the user device 100 is located. The noise sensor 114, when implemented by a microphone(s), may be carried by the user device 100 at one or more locations, such as on a lid of the user device 100, on a base of the user device 100 proximate to the keyboard 126, etc. For example, the noise sensor 114 may determine that if no audible sounds are detected. The reverse pulse circuitry 102 is to use the noise sensor 114 to determine the noise level in decibels (dBA) of the fan(s) 106 in the first mode (e.g., cooling mode) and the second mode (e.g., maintenance mode). In some examples, based on the noise sensor 114 determining that there is a sufficient amount of ambient noise present, the reverse pulse circuitry 102 is to operate the fan(s) 106, as the noise level generated by the fan(s) 106 will not significantly distract the user.

The example operating system monitor 116 is to determine a usage level (e.g., a computational usage level) of the processor 128. For example, if the processor 128 is executing a hardware-intensive task (e.g., gaming, video editing, a high usage task) that requires more electrical power than a hardware-light task (e.g., browsing a webpage, editing a document, a low usage task), the operating system monitor 116 is to determine that there is a high usage level. For example, if the processor 128 is executing a hardware-light task, the operating system monitor 116 determines that there is a low usage level. Based on the usage level (e.g., usage indication), the reverse pulse circuitry 102 may determine that the maintenance mode of the fan(s) 106 is to be activated. For example, a high usage level (e.g., gaming, executing a hardware-intensive task) produces a significant amount of heat, so the fan(s) 106 are rotating at a relatively high speed for a relatively longer time to remove the generated heat. If the user device 100 has been operating at a high usage level for some time, more dust tends to accumulate in the user device 100. Based on the correspondence between the time for which the fan(s) 106 are in cooling mode and the dust accumulated, the reverse pulse circuitry 102 determines when to reverse-pulse the fan(s) 106 to remove the dust. In some examples, the usage level may be estimated (e.g., determined) based on the human interface devices (e.g., mice, keyboards, gaming controllers). For example, if a gaming controller is communicatively coupled to the user device 100, the operating system monitor 116 may estimate that the usage level is a high usage level, as there is a likely probability the user is gaming with the gaming controller that is communicatively coupled to the user device 100.

The example GPS 118 is utilized to determine the location of the user device 100. In some examples, the GPS 118 may be utilized to determine that whether the user device 100 is located in a position and/or location corresponding to relatively dust levels and/or heat levels. For example, if the user device 100 is in a hot and dusty climate, determined based on the location data generated by the GPS 118, the fan(s) 106 may be activated in maintenance mode more frequently than if the user device 100 is in a relatively cold room with a relatively low dust level, for example.

According to examples disclosed herein, the power sensor 120 is to determine if the power source 112 (e.g., battery) is charging or releasing electrical power. For example, if the power sensor 120 determines that the user device 100 is charging (e.g., the power source 112 is charging), the reverse pulse circuitry 102 may determine that the fan(s) 106 are to be activated in maintenance mode.

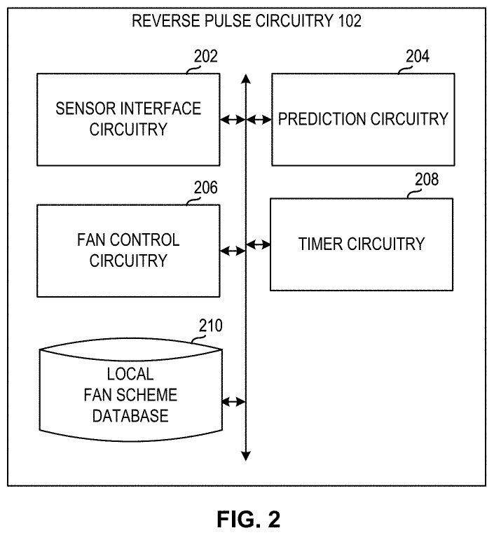

The example network interface 122 is communicatively coupled to the cloud 130 (e.g., the Internet). The network interface 122 may access an example online fan rotation database 132 that includes different pulse patterns (e.g., rotation schemes) for applying the pulsed power to reverse rotate the fan(s) 106. For example, the user device 100 may retrieve from the online fan rotation database 132 a first pulse pattern (e.g., apply electrical power for five seconds, pause for three seconds, apply electrical power for five seconds). In some examples, the online fan rotation database 132 is implemented within the reverse pulse circuitry 102, as illustrated in the example of FIG. 2.

FIG. 2 is a block diagram of example reverse pulse circuitry of the user device 100 of FIG. 1. The reverse pulse circuitry 102 is to determine when to apply pulsed power to the fan(s) 106 such that the fan(s) 106 reverse rotate in a pulse pattern (e.g., a pulsed reverse direction movement). The reverse pulse circuitry 102 of FIG. 2 may be instantiated (e.g., creating an instance of, bring into being for any length of time, materialize, implement, etc.) by processor circuitry such as a central processing unit executing instructions. Additionally or alternatively, the reverse pulse circuitry of FIG. 2 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 2 may, thus, be instantiated at the same or different times. Some or all of the circuitry may be instantiated, for example, in one or more threads executing concurrently on hardware and/or in series on hardware. Moreover, in some examples, some or all of the circuitry of FIG. 2 may be implemented by microprocessor circuitry executing instructions to implement one or more virtual machines and/or containers.

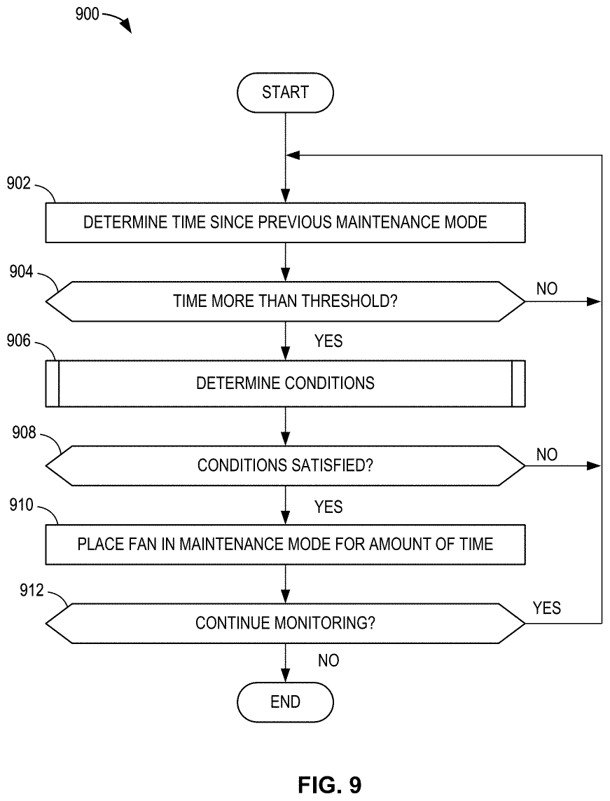

The reverse pulse circuitry 102 includes example sensor interface circuitry 202, example prediction circuitry 204, example fan control circuitry 206, example timer circuitry 208, and an example local fan scheme database 210. In the illustrated example of FIG. 2, the sensor interface circuitry 202 is to retrieve (e.g., obtain, receive) data from the sensors of the user device 100 of FIG. 1. In some examples, the sensor interface circuitry 202 is instantiated by processor circuitry executing sensor interface instructions and/or configured to perform operations such as those represented by the flowcharts of FIGS. 9-11. For example, the sensor interface circuitry 202 is to retrieve at least one of temperature data generated by the temperature sensor 108, motion data generated by the motion sensor 110, user presence data generated by the user presence detection sensor 104, operating system data from the operating system monitor 116, noise level data from the noise sensor 114, and power indication data from the power sensor 120. After the sensor interface circuitry 202 retrieves the sensor data, the prediction circuitry 204 determines when to apply the pulsed power based on the sensor data. For example, in response to temperature data indicating that a component of the user device 100 (e.g., the processor 128, an external body or skin of a laptop) is relatively hot, the prediction circuitry 204 determines to activate the fan control circuitry 206 to cause the fan(s) 106 to rotate in the first mode to cool the user device 100.

In the illustrated example of FIG. 2, the prediction circuitry 204 is to determine when to apply the pulsed power to the fan(s) 106. In some examples, the prediction circuitry 204 is instantiated by processor circuitry executing prediction instructions and/or configured to perform operations such as those represented by the flowcharts of FIGS. 9-11. For example, the prediction circuitry 204 may, based on the sensor data, determine that the fan is to be reverse pulsed. The prediction circuitry 204 is to predict (e.g., estimate) the amount of dust that has accumulated during operation of the fan(s) 106. For example, after the fan(s) 106 have rotated to actively cool the processor 128 for three hours, a layer of dust and/or debris may accumulate. The prediction circuitry 204 may predict the amount of dust that has accumulated and select (e.g., determine) the rotation scheme to apply in the maintenance mode to remove (e.g., clean) the layer of dust that has accumulated. After the prediction circuitry 204 selects the rotation scheme (e.g., a reverse-pulse pattern of three seconds of reversal and one second of pause, a reverse-pulse pattern of five seconds of reversal and one second of pause, etc.), the prediction circuitry 204 determines if the conditions to activate the rotation scheme have been satisfied. For example, a condition may be that the user is not present (e.g., not in close proximity) before the fan(s) 106 enter the maintenance mode and rotate, so that the user does not hear the fan(s) 106. The prediction circuitry 204 retrieves data from the user presence detection sensor 104 to determine if the user is present or not present. For example, if the user is present, the prediction circuitry 204 determines to prevent activation of (i.e., not activate) the fan(s) 106 in a maintenance mode. Alternatively, if the user is not present, the prediction circuitry 204 determines to activate the fan(s) 106 into a maintenance mode. The prediction circuitry 204 may determine to activate the fan(s) 106 based on other conditions or combinations of conditions based on the other sensors illustrated in FIG. 1B.

The example prediction circuitry 204 is to activate the fan(s) 106 based on a rotation scheme or pattern. As used herein, a rotation scheme or pattern represents the direction of rotation (e.g., clockwise, counterclockwise, positive, negative), and duration of time in the direction of rotation, and a duration of time for pausing (e.g., stopping) the fan(s) 106. For example, a first rotation scheme may include three seconds of counterclockwise rotation, followed by one second where the fan(s) 106 are paused (e.g., stopped, halted, zero RPM), followed by three seconds of counterclockwise rotation. The first rotation scheme may be a reverse pulse rotation scheme. In some examples, the first time period has the same duration as the third time period. For example, the fan(s) 106 are to rotate in the reverse direction for three seconds and then another three seconds. In some examples, the fan control circuitry 206 is to pause the fan(s) 106 by using a motor control or fan brakes. In some examples, a fan rotation scheme may include different time periods of rotations. The fan rotation scheme may include a first cycle of rotating the fan(s) 106 for four seconds, pausing the fan(s) 106 for two seconds, rotating the fan(s) 106 for four seconds, followed by a second cycle of rotating the fan(s) 106 for three seconds, pausing the fan(s) 106 for one second, and rotating the fan(s) 106 for five seconds.

In some examples, prediction circuitry 204 is implemented to track (e.g., monitor) the pulse width modulation duty cycle. As used herein, the pulse width modulation duty cycle is the time to apply the electrical power (e.g., the time of the pulse) and the time to pause the application of the electrical power (e.g., the time in between the pulses). In some examples, the prediction circuitry 204 may track the pulse width modulation duty cycle by querying the time elapsed from the timer circuitry 208.

In some examples, the prediction circuitry 204 utilizes and/or includes a tachometer to track utilization of the fan(s) 106. For example, the prediction circuitry 204 determines, with the tachometer, the number of rotations of the fan(s) 106. For example, the prediction circuitry 204 may measure the rotations per minute (RPM) of the fan(s) 106 to generate a measured fan RPM (e.g., measured rotations). The prediction circuitry 204 may generate an expected fan RPM (e.g., predicted fan RPM, expected rotations) based on the electrical power sent to the motor of the fan(s) 106. The example prediction circuitry 204 is to compare the expected fan RPM with the measured fan RPM. Based on the comparison, the example prediction circuitry 204 may estimate an amount of dust accumulation on the fan(s) 106. For example, if, during a cooling mode, the measured fan RPM is nine thousand RPM, and the expected fan RPM is nine thousand and five hundred RPM, the prediction circuitry 204 may determine that the dust that accumulated has reached a threshold level to activate the maintenance mode. In such examples, the prediction circuitry 204 compares the expected rotations with the measured rotations to estimate the level of dust accumulation.

In some examples, the prediction circuitry 204 is to determine the time periods of the fan rotation scheme. For example, the prediction circuitry 204 determines the first time period, the second time period, and the third time period of the fan rotation scheme based on the operation time of the fan in the first mode. For example, the prediction circuitry 204 may determine that the first time period of reverse fan rotation is three seconds, the second time period of pausing fan rotation is one second, and the third time period of reverse fan rotation is three seconds. The prediction circuitry 204, based on the operation time of the fan(s) 106 in a cooling mode, may determine that the first time period is to be five seconds rather than three seconds in the first fan rotation scheme (e.g., reverse pulse pattern). For example, if the fan(s) 106 rotated for six hours in a cooling mode, the prediction circuitry 204 may determine that the first time period of applying electrical power is to be three seconds. Alternatively, if the fan(s) 106 rotated for eight hours in a cooling mode, the prediction circuitry 204 may determine that the first time period of applying electrical power is to be five seconds.

In some examples, the prediction circuitry 204 is to monitor the usage of the fan(s) 106, and to adjust a frequency of activating the rotation of the fan(s) 106 based on the usage of the fan(s) 106. For example, the prediction circuitry 204 may determine that the fan(s) 106 are in a high-usage state for three hours due to a three hour hardware-intensive task (e.g., a three hour video editing session). Based on the monitoring (e.g., determining the fan(s) 106 are in the high-usage state for three hours), the prediction circuitry 204 adjusts (e.g., increases, decreases) the frequency of activating the maintenance mode of the fan(s) 106. For example, the prediction circuitry 204 may, in response to light fan usage, activate the maintenance mode at a first frequency of once a day. Alternatively, in response to relatively heavy fan usage, the prediction circuitry 204 may activate the maintenance mode at a second frequency of twice a day (e.g., an increased frequency from the first frequency).

In the illustrated example of FIG. 2, the fan control circuitry 206 is to control the fan(s) 106. In some examples, the fan control circuitry 206 is instantiated by processor circuitry executing fan control instructions and/or configured to perform operations such as those represented by the flowcharts of FIGS. 9-11. For example, the fan control circuitry 206 is to apply electrical power in the reverse direction. For example, in response to the prediction circuitry 204 activating a reverse pulse rotation scheme, the fan control circuitry 206 is to cause the fan(s) 106 to rotate according to the selected reverse pulse rotation scheme. For example, the fan control circuitry 206 may be implemented by a fan direction pin and 5-pin fan connector. In some examples, the fan control circuitry 206 may be implemented by fan controller chip with a pulse width modulation table split feature. In some examples, the fan control circuitry 206 is implemented by a motor that is to brake (e.g., reduce the speed) of the fan(s) 106 to a stop (e.g., an RPM of zero) and accelerate (e.g., increase the speed) of the fan(s) 106 to a desired RPM level (e.g., nine thousand RPM).

In the illustrated example of FIG. 2, the timer circuitry 208 is to determine how long the fan(s) 106 have been rotating. In some examples, the timer circuitry 208 is instantiated by processor circuitry executing timer instructions and/or configured to perform operations such as those represented by the flowcharts of FIGS. 9-11. For example, the timer circuitry 208 is to track (e.g., monitor) a duration of how long the fan(s) 106 have been in an operation mode (e.g., a cooling mode, a maintenance mode). The prediction circuitry 204 is to retrieve (e.g., access) the time elapsed from the timer circuitry 208. In some examples, where the prediction circuitry 204 includes a tachometer, the prediction circuitry 204 uses the time elapsed from the timer circuitry 208 determine the number of revolutions of the fan(s) 106 that occurred in a minute.

In the illustrated example of FIG. 2, the local fan scheme database 210 stores fan rotation schemes and pulse width modulation duty cycles. As used herein, a pulse width modulation duty cycle determines the characteristics of a pulse width modulated power signal to be applied to the fan(s) 106 (e.g., the electrical signal that causes the fan to rotate, may be applied for five seconds, then the electrical signal may be stopped for two seconds in a repeating pattern). The local fan scheme database 210 stores fan rotation schemes that relate to the movement and rotation of the fan(s) 106 (e.g., the fan(s) 106 are to rotate in the reverse direction for five seconds, then stopped for two seconds). The pulse width modulation duty cycle may not correspond to the fan rotation scheme (e.g., the electrical pulses sent do not correspond to when the fan(s) 106 are rotating and stopped). The local fan scheme database 210 of FIG. 2 is implemented by any memory, storage device and/or storage disc for storing data such as, for example, flash memory, magnetic media, optical media, solid state memory, hard drive(s), thumb drive(s), etc. Furthermore, the fan rotation schemes stored in the local fan scheme database 210 may be in any data format such as, for example, binary data, comma delimited data, tab delimited data, structured query language (SQL) structures, etc. While, in the illustrated example, the example local fan scheme database 210 is illustrated as a single device, the local fan scheme database 210 and/or any other data storage devices described herein may be implemented by any number and/or type(s) of memories. In some examples, the local fan scheme database 210 is instantiated by processor circuitry executing fan scheme database instructions and/or configured to perform operations such as those represented by the flowcharts of FIGS. 9-11. The network interface 122 may retrieve fan rotation schemes from an internet database such as the online fan rotation database 132 of FIG. 1B and store the fan rotation schemes in the local fan scheme database 210.

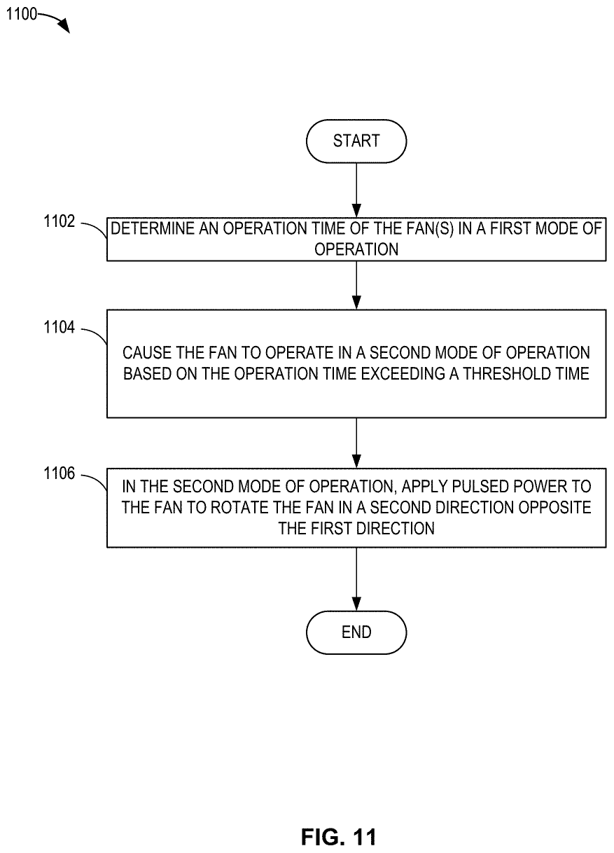

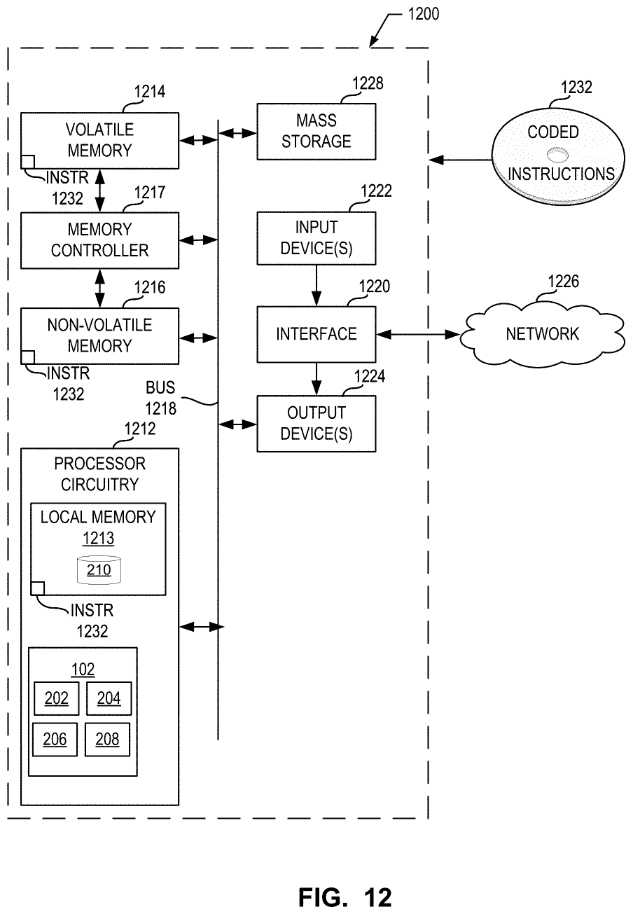

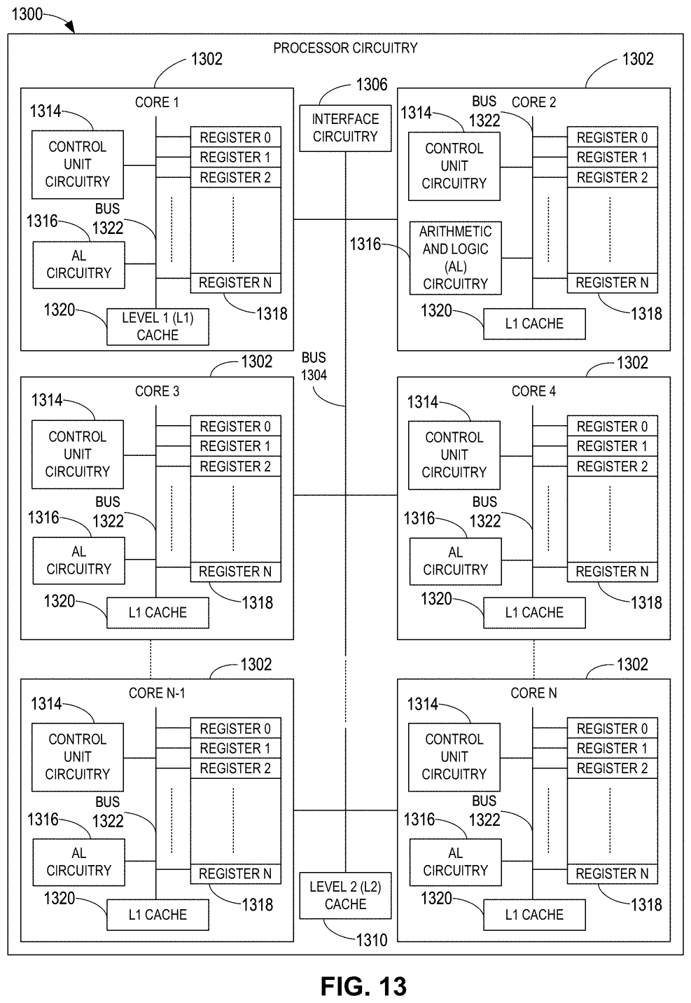

In some examples, the reverse pulse circuitry 102 includes means for determining an operation time of the fan(s) 106 in the first mode. For example, the means for determining an operation time of the fan(s) 106 in the first mode may be implemented by the timer circuitry 208. In some examples, the timer circuitry 208 may be instantiated by processor circuitry such as the example processor circuitry 1212 of FIG. 12. For instance, the timer circuitry 208 may be instantiated by the example microprocessor 1300 of FIG. 13 executing machine executable instructions such as those implemented by at least block 902 of FIG. 9 and block 1102 of FIG. 11. In some examples, the timer circuitry 208 may be instantiated by hardware logic circuitry, which may be implemented by an ASIC, XPU, or the FPGA circuitry 1300 of FIG. 13 structured to perform operations corresponding to the machine readable instructions. Additionally or alternatively, the timer circuitry 208 may be instantiated by any other combination of hardware, software, and/or firmware. For example, the timer circuitry 208 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

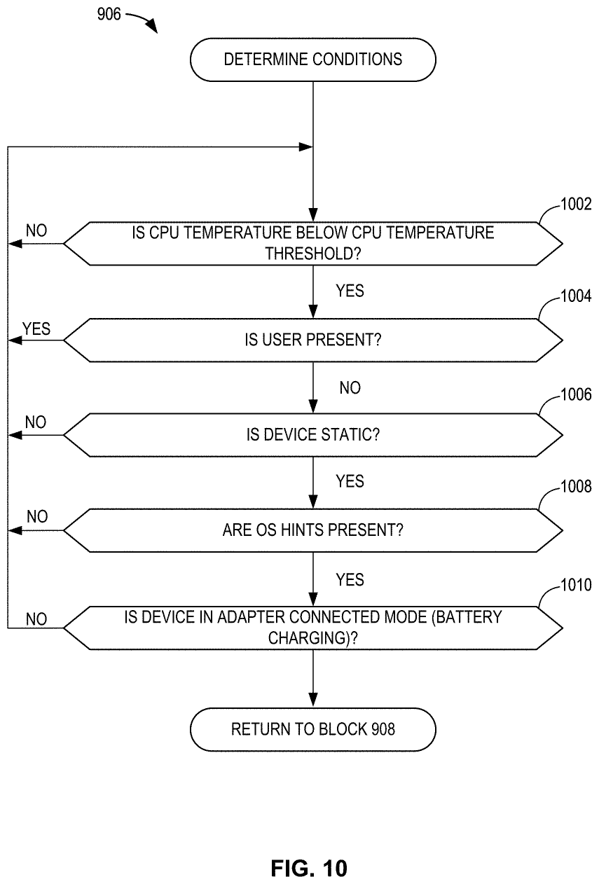

In some examples, the reverse pulse circuitry 102 includes means for causing the fan to operate in a second mode based on the operation time exceeding a threshold time, the second mode corresponding to a maintenance mode of the user device. For example, the means for causing the fan to operate in a second mode based on the operation time exceeding a threshold time, the second mode corresponding to a maintenance mode of the user device may be implemented by the prediction circuitry 204. In some examples, the prediction circuitry 204 may be instantiated by processor circuitry such as the example processor circuitry 1212 of FIG. 12. For instance, the prediction circuitry 204 may be instantiated by the example microprocessor 1300 of FIG. 13 executing machine executable instructions such as those implemented by at least blocks 904, 906, 908, 912 of FIG. 9, blocks 1002, 1004, 1006, 1008, 1010 of FIG. 10, and block 1104 of FIG. 11. In some examples, the prediction circuitry 204 may be instantiated by hardware logic circuitry, which may be implemented by an ASIC, XPU, or the FPGA circuitry 1300 of FIG. 13 structured to perform operations corresponding to the machine readable instructions. Additionally or alternatively, the prediction circuitry 204 may be instantiated by any other combination of hardware, software, and/or firmware. For example, the prediction circuitry 204 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the reverse pulse circuitry 102 includes means for applying pulsed power causing the fan to operate in the second mode based on the operation time exceeding a threshold time. For example, the means for applying pulsed power causing the fan to operate in a second mode based on the operation time exceeding a threshold time may be implemented by the fan control circuitry 206. In some examples, the fan control circuitry 206 may be instantiated by processor circuitry such as the example processor circuitry 1212 of FIG. 12. For instance, the fan control circuitry 206 may be instantiated by the example microprocessor 1300 of FIG. 13 executing machine executable instructions such as those implemented by at least block 910 of FIG. 9 and block 1106 of FIG. 11. In some examples, the fan control circuitry 206 may be instantiated by hardware logic circuitry, which may be implemented by an ASIC, XPU, or the FPGA circuitry 1300 of FIG. 13 structured to perform operations corresponding to the machine readable instructions. Additionally or alternatively, the fan control circuitry 206 may be instantiated by any other combination of hardware, software, and/or firmware. For example, the fan control circuitry 206 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

While an example manner of implementing the reverse pulse circuitry 102 of FIG. 1 is illustrated in FIG. 2, one or more of the elements, processes, and/or devices illustrated in FIG. 2 may be combined, divided, re-arranged, omitted, eliminated, and/or implemented in any other way. Further, the example sensor interface circuitry 202, the example prediction circuitry 204, the example fan control circuitry 206, the example timer circuitry 208, and/or, more generally, the example reverse pulse circuitry 102 of FIG. 1, may be implemented by hardware alone or by hardware in combination with software and/or firmware. Thus, for example, any of the example sensor interface circuitry 202, the example prediction circuitry 204, the example fan control circuitry 206, the example timer circuitry 208, and/or, more generally, the example reverse pulse circuitry 102 of FIG. 1, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example reverse pulse circuitry 102 of FIG. 1 may include one or more elements, processes, and/or devices in addition to, or instead of, those illustrated in FIG. 2, and/or may include more than one of any or all of the illustrated elements, processes and devices.

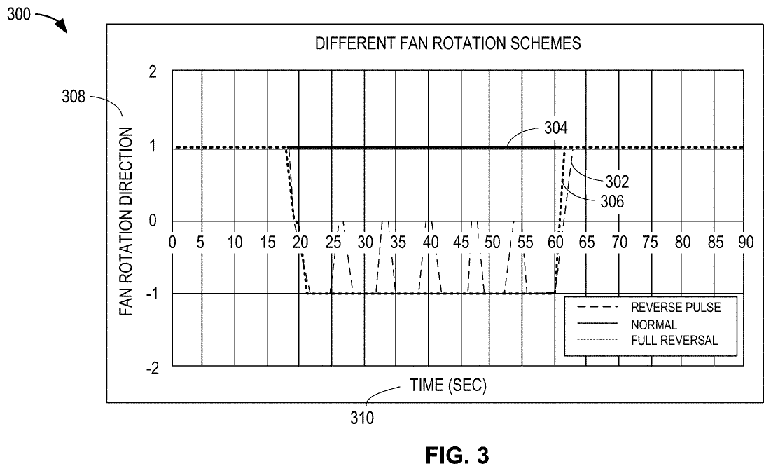

FIG. 3 is an illustration of example fan rotation schemes that can be implemented by the example reverse pulse circuitry 102 shown in FIG. 2. The fan rotation schemes illustrated in an example graph 300 of FIG. 3 include an example first fan rotation scheme 302, an example second fan rotation scheme 304, and an example third fan rotation scheme 306. The first fan rotation scheme 302 is a reverse pulse pattern. The second fan rotation scheme 304 is a normal forward rotation pattern. The third fan rotation scheme 306 is a full reversal pattern.

A vertical axis 308 corresponds to the fan rotation direction, where positive one denotes a forward (e.g., clockwise, normal, standard) direction and negative one denotes a backwards (e.g., counter-clockwise, reversed) direction. A horizontal axis 310 corresponds to a time in seconds. From zero seconds to fifteen seconds, the fan(s) 106 (not shown) have been rotating in the forward direction in the first mode (e.g., cooling mode). At fifteen seconds, the reverse pulse circuitry 102 has determined to activate the fan rotation schemes to enter a maintenance mode.

The example first fan rotation scheme 302 (e.g., the reverse pulse pattern) applies electrical power that is to change the direction of rotation for the fan(s) 106. At twenty-two seconds, the fan(s) 106 are rotating in the reverse direction based on the applied electrical power from the reverse pulse circuitry 102. At twenty-six seconds, the reverse pulse circuitry 102 has stopped the rotation of the fan(s) 106 by reducing the RPM to zero. In some examples, the reverse pulse circuitry 102 is to use the fan control circuitry 206 to brake (e.g., reduce the fan speed, stop, pause) the fan(s) 106. At twenty-eight seconds, the reverse pulse circuitry 102 re-applies the electrical power to cause the fan(s) 106 to rotate in the reverse direction. For example, the reverse pulse circuitry 102 causes the fan control circuitry 206 to increase the speed of the fan(s) 106 until the fan(s) 106 reach a predetermined RPM value. The pulses continue to cause the fan(s) 106 to rotate reverse direction, until sixty seconds, when the reverse pulse circuitry 102 determines to exit the maintenance mode (e.g., dust removal mode) and enter the cooling mode. The fan(s) 106 are rotating in the forward direction from sixty-five seconds to ninety seconds. While the fan(s) 106 are in maintenance mode, the reverse pulse circuitry 102 is to control the fan(s) 106 based on the fan rotation scheme which has a repeating pattern of reverse rotation for a time period and pauses for a time period.

The second fan rotation scheme 304 (e.g., the normal forward rotation pattern) utilizes an application of electrical power to maintain the fan(s) 106 rotating in the forward direction. The direction of the second fan rotation scheme 304 is the same from zero seconds to ninety seconds (e.g., in a forward direction), despite the second fan rotation scheme 304 entering a maintenance mode at twenty seconds. During the maintenance mode that occurs between twenty seconds and sixty seconds, the fan(s) 106 are to rotate in the forward direction.

The third fan rotation scheme 306 (e.g., a full reversal scheme) applies electrical power to switch the rotation of the fan(s) 106 for the entire maintenance mode. The example maintenance mode begins at twenty seconds and ends at sixty seconds. The third fan rotation scheme 306 is louder than the first fan rotation scheme 302 because the RPM that corresponds to the third fan rotation scheme 306 is a higher value than the RPM that corresponds to the first fan rotation scheme 302. The third fan rotation scheme 306 sustains the same or similar RPM level and corresponding noise level for the maintenance period, while the first fan rotation scheme 302 oscillates the RPM level and the corresponding noise level for the pulses. The average RPM level and the average noise level for the first fan rotation scheme 302 is lower than the RPM level and the noise level for the third fan rotation scheme 306.

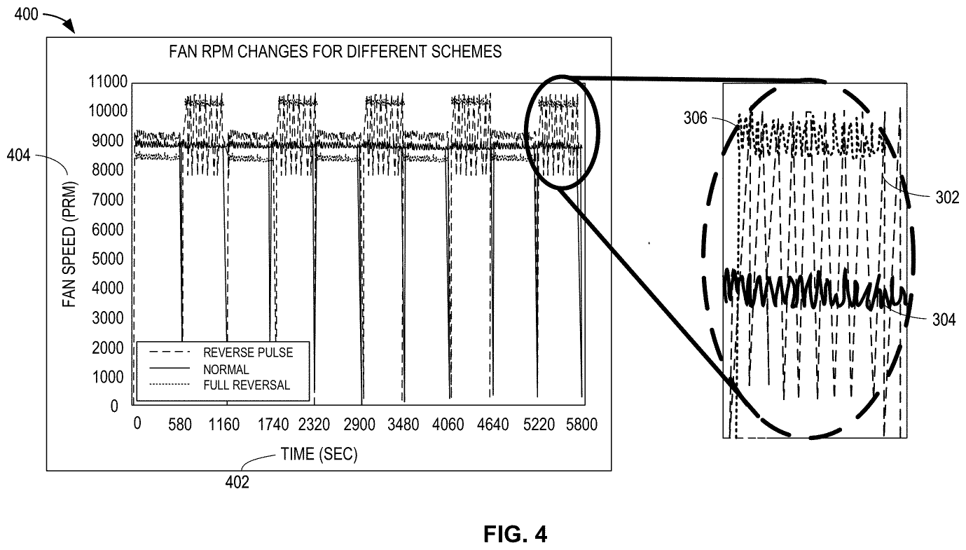

FIG. 4 is an illustration of a speed of example fan rotation schemes that can be implemented by the example reverse pulse circuitry 102 shown in FIG. 2. An example graph 400 includes a horizontal axis 402, which represents time measured in seconds and a vertical axis 404, which represents fan speed measured in rotations per minute (RPM). The second fan rotation scheme 304 (e.g., the normal forward rotation pattern) remains at about nine thousand RPM for the maintenance period and the cooling period. Due to the data collection time interval used in generating the graph 400, the line that tracks the fan speed of the first fan rotation scheme 302 does not reach zero. However, in reality, the RPM speed of the fan(s) 106 can reach zero (e.g., the fan stops) for a moment of time (e.g., one second, one millisecond, five seconds) before the RPM is increased for the duration of the pulse. The first fan rotation scheme 302 fluctuates (e.g., oscillates) between ten thousand RPM and zero RPM, even though, based on data collection interval, the graph illustrates that the first fan rotation scheme 302 fluctuates between ten thousand RPM and eight thousand RPM. The third fan rotation scheme 306 increases the RPM to ten thousand RPM for the entire maintenance period (e.g., forty seconds). The first fan rotation scheme 302 increases and decreases the average RPM within a shorter duration (e.g., five to seven seconds), which effectively reduces the RPM compared to the third fan rotation scheme 306. The increase and decrease of RPM of the first fan rotation scheme allows for a smoother noise level transition, thereby enhancing the noise quality.

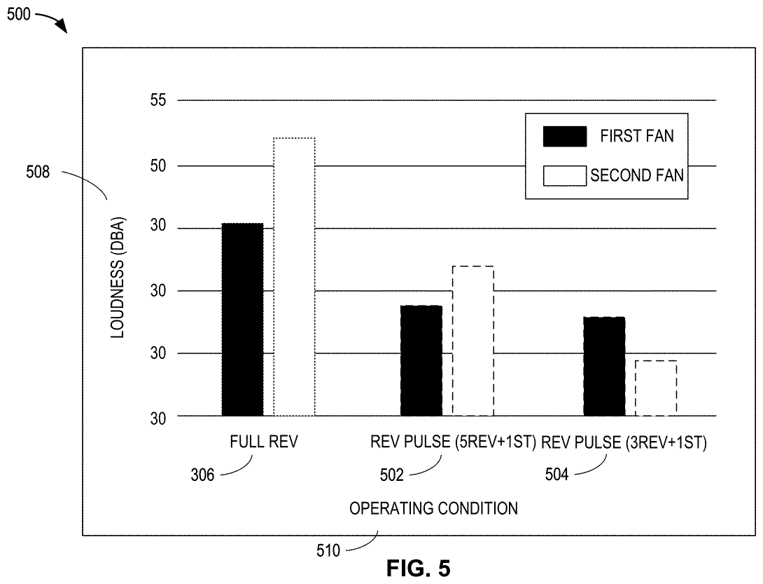

FIG. 5 is an illustration of a loudness comparison of example fan rotation schemes implemented by the example reverse pulse circuitry 102 of FIG. 2. The graph 500 illustrates loudness in decibels (dBA) between two fans. A horizontal axis 510 illustrates the different operating conditions (e.g., fan rotation schemes) and a vertical axis 508 illustrates the loudness in decibels. The two fans illustrate the same trend. The example third fan rotation scheme 306 (e.g., full reversal scheme) is louder in dBA than the example first reverse pulse scheme 502 and the example second reverse pulse scheme 504. The first reverse pulse scheme 502 is similar to the first fan rotation scheme 302 of FIG. 3 (e.g., reverse pulse scheme). However, the first reverse pulse scheme 502 has defined five seconds of applying electrical power to reverse the rotation of the fan(s) 106. The second reverse pulse scheme 504 is similar to the first fan rotation scheme 302 of FIG. 3 (e.g., reverse pulse scheme). However, the second reverse pulse scheme 504 has defined three seconds of applying electrical power to reverse the rotation of the fan(s) 106.

In some examples where the reverse pulse circuitry 102 is to thoroughly remove dust, the reverse pulse circuitry 102 determines to use the first reverse pulse scheme 502, which includes five seconds (e.g., rather than three seconds of the second reverse pulse scheme 504) of applying electrical power to reverse the rotation of the fan(s) 106. The first reverse pulse scheme 502 includes five seconds of rotation of the fan(s) 106 prior to one second of pausing the rotation of the fan(s) 106. The second reverse pulse scheme 504 includes three seconds of rotation of the fan(s) 106 prior to one second of pausing the rotation of the fan(s) 106. In some examples, where the reverse pulse circuitry 102 is to moderately remove dust, the reverse pulse circuitry 102 determines to use the second reverse pulse scheme 504, which consists of three seconds of applying electrical power to reverse the rotation of the fan(s) 106 prior to one second of pausing the fan(s) 106. The second reverse pulse scheme 504 is relatively quieter than the first reverse pulse scheme 502. In some examples, the reverse pulse circuitry 102 may select the reverse pulse scheme with the quieter noise level (e.g., second reverse pulse scheme 504) rather than the reverse pulse scheme with for more thorough cleaning (e.g., first reverse pulse scheme 502).

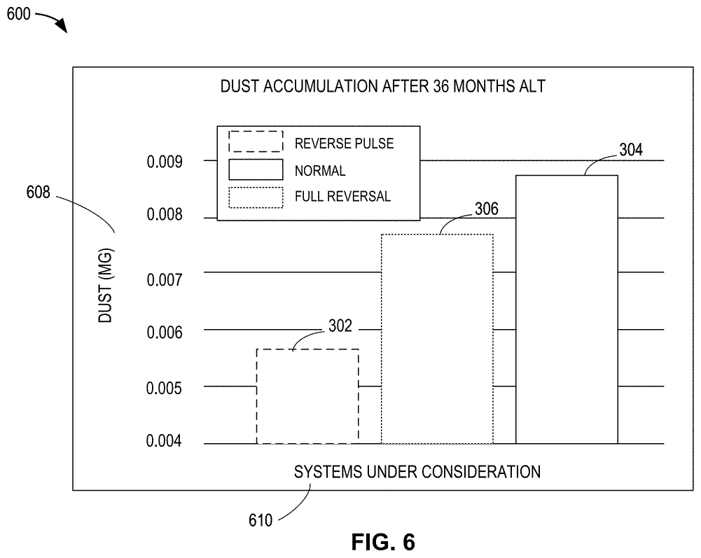

FIG. 6 is an illustration of a dust accumulation comparison of example fan rotation schemes implemented by the example reverse pulse circuitry 102 of FIG. 2. The graph 600 illustrates the dust that accumulated (e.g., illustrated on the vertical axis 608) in the heat exchanger (HX) fin spacing in thirty-six months of accelerated life testing (ALT) for three identical Tiger-Lake™ PC systems (e.g., TGL-U GCS notebook PC systems), which are illustrated on the horizontal axis 610. The first TGL system utilizes the first fan rotation scheme 302 (e.g., reverse pulse pattern) for maintenance. The second TGL system utilizes the second fan rotation scheme 304 (e.g., normal forward rotation pattern) for maintenance. The third TGL system utilized the third fan rotation scheme 306 (e.g., full reversal) for maintenance. The first TGL system that used the first fan rotation scheme 302 had the least dust that accumulated (e.g., in between 0.005 milligrams and 0.006 milligrams of dust) compared with the other TGL systems. The dust level that accumulated for the second TGL system that used the second fan rotation scheme 304 was above 0.007 milligrams of dust. The dust level that accumulated for the third TGL system that used the third fan rotation scheme 306 was above 0.008 milligrams of dust.

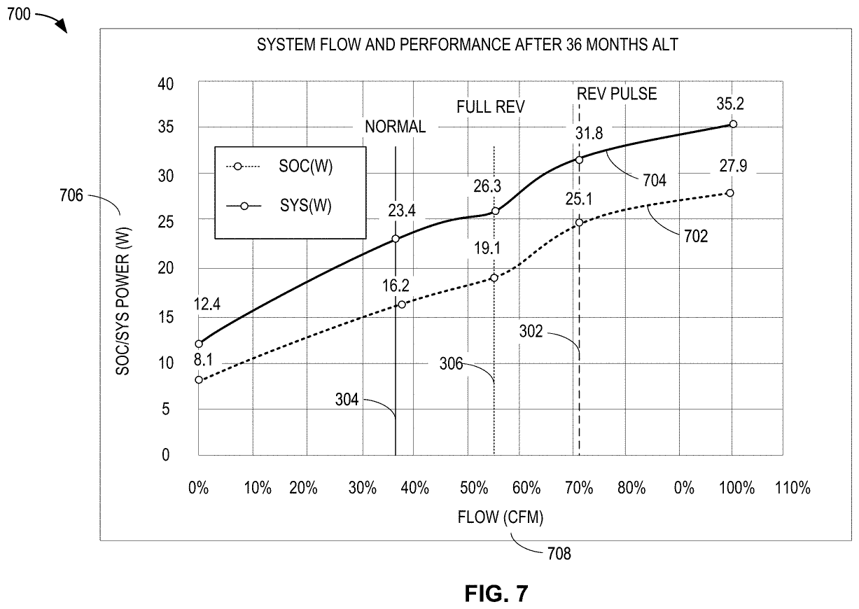

FIG. 7 is an illustration of an example system performance comparison of example fan rotation schemes implemented by the example reverse pulse circuitry 102 of FIG. 2. An example graph 700 illustrates the system flow and the performance after thirty-six months of accelerated life testing (ALT) for a system-on-a-chip 702 (e.g., SoC) and a system 704 (e.g., Sys). The performance is measured in watts on a vertical axis 706. The flow is measured in cubic feet per minute (e.g., CFM) as a percentage on a horizontal axis 708. The system 704 had a higher power to flow ratio compared to the system-on-a-chip 702. The graph also illustrates the rotation schemes where the first fan rotation scheme 302 (e.g., reverse pulse rotation scheme), the second fan rotation scheme 304 (e.g., normal forward rotation pattern), and the third fan rotation scheme 306 (e.g., full reverse rotation scheme) intersect the system-on-a-chip 702 and the system 704. The first fan rotation scheme 302 (e.g., reverse pulse rotation scheme) contributed to the highest flow and the highest power for both the system-on-a-chip 702 and the system 704 compared with the second fan rotation scheme 304 (e.g., normal forward rotation pattern) and the third fan rotation scheme 306 (e.g., full reverse rotation scheme).

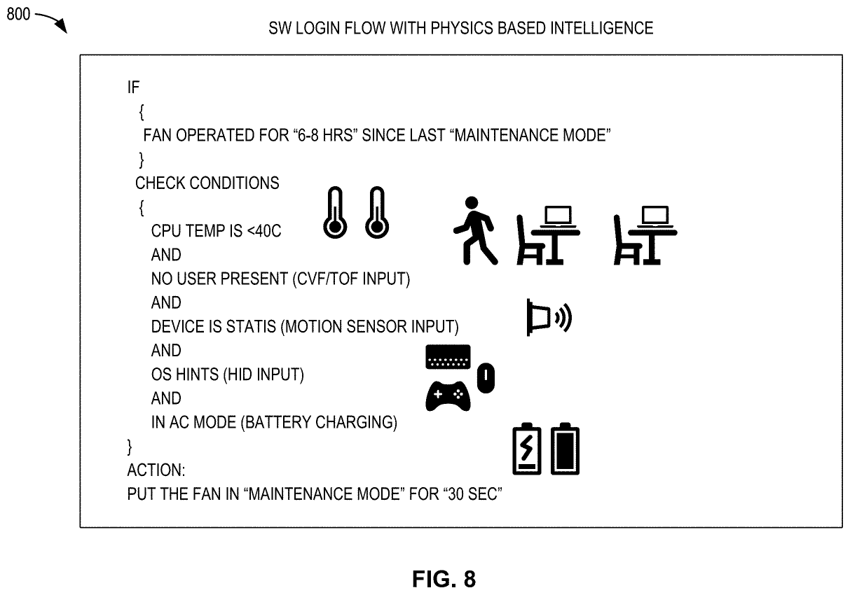

FIG. 8 is a pseudocode representative of example machine readable instructions and/or operations 800 that may be executed by example processor circuitry to implement the reverse pulse circuitry 102 of FIG. 2 to place the fan in maintenance mode. The operations 800 include an if/then statement. The reverse pulse circuitry 102 determines the time elapsed since the previous maintenance mode before checking conditions by querying the timer circuitry 208. If the conditions are satisfied, the reverse pulse circuitry 102 places the fan(s) 106 into maintenance mode. In the example of FIG. 8, the fan(s) 106 are placed into maintenance mode for thirty seconds. The pseudocode representative of FIG. 8 is described in more detail in connection with FIGS. 9 and 10.

Flowcharts representative of example machine readable instructions, which may be executed to configure processor circuitry to implement the reverse pulse circuitry 102 of FIG. 2, are shown in FIGS. 9-11. The machine readable instructions may be one or more executable programs or portion(s) of an executable program for execution by processor circuitry, such as the processor circuitry 1212 shown in the example processor platform 1200 discussed below in connection with FIG. 12 and/or the example processor circuitry discussed below in connection with FIGS. 13 and/or 14. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowcharts illustrated in FIGS. 9-11, many other methods of implementing the example reverse pulse circuitry 102 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 9-11 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine readable medium, and non-transitory machine readable storage medium are expressly defined to include any type of computer readable storage device and/or storage disk and to exclude propagating signals and to exclude transmission media. As used herein, the terms “computer readable storage device” and “machine readable storage device” are defined to include any physical (mechanical and/or electrical) structure to store information, but to exclude propagating signals and to exclude transmission media. Examples of computer readable storage devices and machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer readable instructions, machine readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 9 is a flowchart representative of example machine readable instructions and/or example operations 900 that may be executed and/or instantiated by processor circuitry to place the fan in maintenance mode. The machine readable instructions and/or the operations 900 of FIG. 9 begin at block 902, at which the prediction circuitry 204 determines an amount of time elapsed since the previous maintenance mode. For example, the prediction circuitry 204 may determine the time since the previous maintenance mode by retrieving an elapsed time measurement from the timer circuitry 208. The timer circuitry 208 is to track the time the fan(s) 106 are in cooling mode and the time the fan(s) are in maintenance mode.

At block 904, the prediction circuitry 204 determines if the time since the previous maintenance mode exceeds a threshold. For example, the prediction circuitry 204 may determine that a maintenance mode is to be activated after every five hours of light usage (e.g., web-browsing, document writing) or after every three hours of heavy usage (e.g., gaming, video editing, etc.). The prediction circuitry 204 may determine the type of computer usage (e.g., hardware-light or hardware-intensive), select the corresponding threshold based on the usage, and then compare the time retrieved from the timer circuitry 208 to the selected threshold. If, for example, the time has not been more than the threshold (e.g., block 904 returns a result of NO), control returns to block 902. If, for example, the time has been more than the threshold (e.g., block 904 returns a result of YES), control advances to block 906.

At block 906, the prediction circuitry 204 determines the conditions that are to be satisfied before the fan(s) 106 are to be placed in maintenance mode. For example, there are more conditions to be satisfied than the time since the last maintenance mode. The conditions that are determined are further described in connection with FIG. 10.

At block 908, the prediction circuitry 204 determines if the conditions are satisfied. In response to the conditions not being satisfied (e.g., block 908 returns a result of NO), control returns to block 902. In response to the conditions being satisfied (e.g., block 908 returns a result of YES), control advances to block 910.

At block 910, the fan control circuitry 206 controls, places and/or sets the fan(s) 106 in maintenance mode for an amount of time. For example, the prediction circuitry 204 may determine to use a fan rotation scheme that is to reverse pulse the fan(s) 106 for four seconds before pausing for two seconds. The fan control circuitry 206 is to apply the electrical power for four seconds, before causing the fan(s) 106 to pause for two seconds. The electrical power is to cause the rotation of the fan(s) 106. The fan rotation scheme is to occur multiple times in one maintenance period (e.g., multiple cycles in one maintenance period). For example, if a first cycle of the rotation scheme is to spin the fans for four seconds, pause for two seconds, spin for four seconds, a second cycle may occur, following the first cycle, where the second cycle is to spin the fans for four seconds, pause for two seconds, and spin for four seconds. In some examples, a fan rotation scheme may include different time periods of rotations. The fan rotation scheme may include a first cycle of rotating the fan(s) 106 for four seconds, pausing the fan(s) 106 for two seconds, rotating the fan(s) 106 for four seconds, followed by a second cycle of rotating the fan(s) 106 for three seconds, pausing the fan(s) 106 for one second, and rotating the fan(s) 106 for five seconds.

At block 912, the prediction circuitry 204 determines to continue monitoring the fan(s) 106. For example, the user device 100 may be powered off, so monitoring may be completed. In response to the prediction circuitry 204 determining to continue monitoring (e.g., block 912 returns a result of YES), control flows to block 902. In response to the prediction circuitry 204 determining to not continue monitoring (e.g., block 912 returns a result of NO), the instructions 900 end.

FIG. 10 is a flowchart representative of example machine readable instructions and/or example operations 906 that may be executed and/or instantiated by processor circuitry to determine if the conditions are satisfied to place the fan(s) 106 in maintenance mode. The machine readable instructions and/or the operations 906 begin at block 906 of FIG. 9, at which the prediction circuitry 204 determines the conditions. The prediction circuitry 204 at block 906 determines the conditions that are satisfied to place the fan(s) 106 in maintenance mode based on the sensors 104, 108, 110, 120 and operating system monitor 116 of FIG. 1B. The example of FIG. 10 illustrates the prediction circuitry 204 using data from the temperature sensor 108, the user presence detection sensor 104, the motion sensor 110, the operating system monitor 116, and the power sensor 120. In other examples, the prediction circuitry 204 may use other sensors to determine other conditions.

At block 1002, the prediction circuitry 204 determines if the CPU temperature is below a temperature threshold. For example, the prediction circuitry 204 may determine the CPU temperature is above a temperature threshold by accessing the temperature of the CPU from the temperature sensor 108. In some examples, the temperature threshold is forty degrees Celsius (e.g., one hundred and four degrees Fahrenheit). The prediction circuitry 204 will not transition the fan(s) 106 from cooling mode to maintenance mode if the CPU temperature is above the threshold. In response to the prediction circuitry 204 determining that the CPU temperature is not below the CPU temperature threshold (e.g., block 1002 returns a result of NO), control returns to block 1002. In response to the prediction circuitry 204 determining that the CPU temperature is below the CPU temperature threshold (e.g., block 1002 returns a result of YES), control advances to block 1004.

At block 1004, prediction circuitry 204 determines if a user (e.g., operator) of the user device 100 is present. For example, the prediction circuitry 204 may determine if a user if present by accessing the data from the user presence detection sensor 104. In some examples, the user presence detection sensor 104 determines if a user of the user device 100 is present (e.g., nearby) by using a front camera to generate images in the field of view of the user device 100. In some examples, the prediction circuitry 204 determines that the user is not to hear the fan(s) 106 that are in maintenance mode. In some examples, the prediction circuitry 204 is to retrieve data from the user presence detection sensor 104 and determine if the fan(s) 106 are to be placed in maintenance mode based on the retrieved data. In response to the prediction circuitry 204 determining that the user is present (e.g., block 1002 returns a result of YES), control returns to block 1002. In response to the prediction circuitry 204 determining that the user is not present (e.g., block 1004 returns a result of NO), control advances to block 1006.

At block 1006, the prediction circuitry 204 determines if the user device 100 is stationary. For example, the prediction circuitry 204 may determine that the user device 100 is stationary based on the motion sensor 110. In some examples, the motion sensor 110 is implemented by a gyroscope or an accelerometer. Additionally or alternatively, the prediction circuitry 204 determines to not put the fan(s) 106 in maintenance mode if the user device 100 is in motion. At least one reason to not put the fan(s) 106 in maintenance if the user device 100 is in motion is that a hand of a user may block the fan grating. A blocked fan grating may not allow air to flow (e.g., enter or exit the fan grating). In some examples, if the fan grating is blocked by a user's hand, dust may be expelled on the user's hand. In response to the prediction circuitry 204 determining that the user device 100 is not stationary (e.g., block 1006 returns a result of NO), control returns to block 1002. In response to the prediction circuitry 204 determining that the user device 100 is static (e.g., block 1006 returns a result of YES), control advances to block 1008.

At block 1008, the prediction circuitry 204 determines if there are operating system hints present. For example, the prediction circuitry 204 may determine the user device 100 is executing a hardware-intensive task (e.g., gaming, video editing, a high usage task) or if the user device 100 is executing a hardware-light task (e.g., browsing a webpage, editing a document, a low usage task) based on an indication from the operating system monitor 116. In some examples, the operating system monitor 116 has access to human input devices (e.g., mice, keyboards, gaming controllers). For example, if the operating system monitor 116 detects a gaming controller or other indication of gaming activity, the prediction circuitry 204 may determine and/or infer that the user device 100 is executing a hardware-intensive task (e.g., there is high usage of the operating system and/or processor 128 of the user device 100). The prediction circuitry 204 may determine that based on the estimated high usage of the operating system, the fan(s) 106 have been running in a cooling mode, which has caused dust to accumulate faster than if there was a low usage of the operating system. The prediction circuitry 204 may then determine that the fan(s) 106 are to enter a maintenance mode. In response to the prediction circuitry 204 determining that the user device 100 is not in a high usage state based on an operating system hint (e.g., block 1008 returns a result of NO), control returns to block 1002. In response to the prediction circuitry 204 determining that the user device 100 is in a high usage state based on an operating system hint (e.g., block 1008 returns a result of YES), control advances to block 1010.

At block 1010, the prediction circuitry 204 determines if the user device 100 is in adapter connected (AC) mode. For example, the prediction circuitry 204 may determine the user device 100 is in AC mode based on if the power source 112 (e.g., battery) is charging. The example prediction circuitry 204 can use the power sensor 120 to determine if the user device 100 is in AC mode. The power sensor 120 is to determine the status of the power source 112. In response to the prediction circuitry 204 determining that the user device 100 is not in AC mode (e.g., block 1010 returns a result of NO), control returns to block 1002. In response to the prediction circuitry 204 determining that the user device 100 is in AC mode (e.g., block 1010 returns a result of YES), control returns to block 908 of FIG. 9. In some examples, if the conditions are satisfied, the prediction circuitry 204 is to instruct the fan control circuitry 206 to place the fan(s) 106 into maintenance mode. The instructions 906 end.

FIG. 11 is a flowchart representative of example machine readable instructions and/or example operations 1100 that may be executed and/or instantiated by processor circuitry to apply pulsed power to the fan. The machine readable instructions and/or the operations 1100 of FIG. 11 begin at block 1102, at which the timer circuitry 208 is to determine an operation time of the fan(s) 106 in a first mode of operation. For example, the timer circuitry 208 is to determine the time elapsed that the fan(s) 106 are in the cooling mode.

At block 1104, the prediction circuitry 204 is to cause the fan(s) 106 operate in a second mode of operation based on the operation time exceeding a threshold time, the second mode of operation corresponding to a maintenance mode of the user device 100. For example, the prediction circuitry 204 is to cause the fan(s) 106 to operate in the maintenance mode based on the conditions being determined including the operation time of the fan(s) 106 in the cooling mode. In particular, the example prediction circuitry 204 is to compare the threshold time with the time determined by the timer circuitry 208. In some examples, the threshold time is in between six and eight hours.

At block, 1106, in the second mode of operation, the fan control circuitry 206 is to apply pulsed power to the fan(s) 106. For example, the fan control circuitry 206 is to apply pulsed power, the pulsed power to rotate the fan(s) 106 in a direction opposite from the first direction. For example, the fan control circuitry 206 is to apply pulsed power to the fan(s) 106 to follow a reversed pulse fan rotation scheme. The instructions 1100 end.

FIG. 12 is a block diagram of an example processor platform 1200 structured to execute and/or instantiate the machine readable instructions and/or the operations of FIGS. 9-11 to implement the reverse pulse circuitry 102 of FIG. 2. The processor platform 1200 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing device.

The processor platform 1200 of the illustrated example includes processor circuitry 1212. The processor circuitry 1212 of the illustrated example is hardware. For example, the processor circuitry 1212 can be implemented by one or more integrated circuits, logic circuits, FPGAs, microprocessors, CPUs, GPUs, DSPs, and/or microcontrollers from any desired family or manufacturer. The processor circuitry 1212 may be implemented by one or more semiconductor based (e.g., silicon based) devices. In this example, the processor circuitry 1212 implements the sensor interface circuitry 202, the prediction circuitry 204, the fan control circuitry 206, and the timer circuitry 208.

The processor circuitry 1212 of the illustrated example includes a local memory 1213 (e.g., a cache, registers, etc.). The processor circuitry 1212 of the illustrated example is in communication with a main memory including a volatile memory 1214 and a non-volatile memory 1216 by a bus 1218. The volatile memory 1214 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1216 may be implemented by flash memory and/or any other desired type of memory device. Access to the main memory 1214, 1216 of the illustrated example is controlled by a memory controller 1217. In some examples, the main memory 1214, 1216 implements the local fan scheme database 210.

The processor platform 1200 of the illustrated example also includes interface circuitry 1220. The interface circuitry 1220 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1222 are connected to the interface circuitry 1220. The input device(s) 1222 permit(s) a user to enter data and/or commands into the processor circuitry 1212. The input device(s) 1222 can be implemented by, for example, an audio sensor, a microphone, a camera (still or video), a keyboard, a button, a mouse, a touchscreen, a track-pad, a trackball, an isopoint device, and/or a voice recognition system.

One or more output devices 1224 are also connected to the interface circuitry 1220 of the illustrated example. The output device(s) 1224 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1220 of the illustrated example, thus, typically includes a graphics driver card, a graphics driver chip, and/or graphics processor circuitry such as a GPU.

The interface circuitry 1220 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1226. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 1200 of the illustrated example also includes one or more mass storage devices 1228 to store software and/or data. Examples of such mass storage devices 1228 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine readable instructions 1232, which may be implemented by the machine readable instructions of FIGS. 9-11, may be stored in the mass storage device 1228, in the volatile memory 1214, in the non-volatile memory 1216, and/or on a removable non-transitory computer readable storage medium such as a CD or DVD.

FIG. 13 is a block diagram of an example implementation of the processor circuitry 1212 of FIG. 12. In this example, the processor circuitry 1212 of FIG. 12 is implemented by a microprocessor 1300. For example, the microprocessor 1300 may be a general purpose microprocessor (e.g., general purpose microprocessor circuitry). The microprocessor 1300 executes some or all of the machine readable instructions of the flowcharts of FIGS. 9-11 to effectively instantiate the reverse pulse circuitry 102 of FIG. 2 as logic circuits to perform the operations corresponding to those machine readable instructions. In some such examples, the reverse pulse circuitry 102 of FIG. 2 is instantiated by the hardware circuits of the microprocessor 1300 in combination with the instructions. For example, the microprocessor 1300 may be implemented by multi-core hardware circuitry such as a CPU, a DSP, a GPU, an XPU, etc. Although it may include any number of example cores 1302 (e.g., 1 core), the microprocessor 1300 of this example is a multi-core semiconductor device including N cores. The cores 1302 of the microprocessor 1300 may operate independently or may cooperate to execute machine readable instructions. For example, machine code corresponding to a firmware program, an embedded software program, or a software program may be executed by one of the cores 1302 or may be executed by multiple ones of the cores 1302 at the same or different times. In some examples, the machine code corresponding to the firmware program, the embedded software program, or the software program is split into threads and executed in parallel by two or more of the cores 1302. The software program may correspond to a portion or all of the machine readable instructions and/or operations represented by the flowcharts of FIGS. 9-11.

The cores 1302 may communicate by a first example bus 1304. In some examples, the first bus 1304 may be implemented by a communication bus to effectuate communication associated with one(s) of the cores 1302. For example, the first bus 1304 may be implemented by at least one of an Inter-Integrated Circuit (I2C) bus, a Serial Peripheral Interface (SPI) bus, a PCI bus, or a PCIe bus. Additionally or alternatively, the first bus 1304 may be implemented by any other type of computing or electrical bus. The cores 1302 may obtain data, instructions, and/or signals from one or more external devices by example interface circuitry 1306. The cores 1302 may output data, instructions, and/or signals to the one or more external devices by the interface circuitry 1306. Although the cores 1302 of this example include example local memory 1320 (e.g., Level 1 (L1) cache that may be split into an L1 data cache and an L1 instruction cache), the microprocessor 1300 also includes example shared memory 1310 that may be shared by the cores (e.g., Level 2 (L2 cache)) for high-speed access to data and/or instructions. Data and/or instructions may be transferred (e.g., shared) by writing to and/or reading from the shared memory 1310. The local memory 1320 of each of the cores 1302 and the shared memory 1310 may be part of a hierarchy of storage devices including multiple levels of cache memory and the main memory (e.g., the main memory 1214, 1216 of FIG. 12). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1302 may be referred to as a CPU, DSP, GPU, etc., or any other type of hardware circuitry. Each core 1302 includes control unit circuitry 1314, arithmetic and logic (AL) circuitry (sometimes referred to as an ALU) 1316, a plurality of registers 1318, the local memory 1320, and a second example bus 1322. Other structures may be present. For example, each core 1302 may include vector unit circuitry, single instruction multiple data (SIMD) unit circuitry, load/store unit (LSU) circuitry, branch/jump unit circuitry, floating-point unit (FPU) circuitry, etc. The control unit circuitry 1314 includes semiconductor-based circuits structured to control (e.g., coordinate) data movement within the corresponding core 1302. The AL circuitry 1316 includes semiconductor-based circuits structured to perform one or more mathematic and/or logic operations on the data within the corresponding core 1302. The AL circuitry 1316 of some examples performs integer based operations. In other examples, the AL circuitry 1316 also performs floating point operations. In yet other examples, the AL circuitry 1316 may include first AL circuitry that performs integer based operations and second AL circuitry that performs floating point operations. In some examples, the AL circuitry 1316 may be referred to as an Arithmetic Logic Unit (ALU). The registers 1318 are semiconductor-based structures to store data and/or instructions such as results of one or more of the operations performed by the AL circuitry 1316 of the corresponding core 1302. For example, the registers 1318 may include vector register(s), SIMD register(s), general purpose register(s), flag register(s), segment register(s), machine specific register(s), instruction pointer register(s), control register(s), debug register(s), memory management register(s), machine check register(s), etc. The registers 1318 may be arranged in a bank as shown in FIG. 5. Alternatively, the registers 1318 may be organized in any other arrangement, format, or structure including distributed throughout the core 1302 to shorten access time. The second bus 1322 may be implemented by at least one of an I2C bus, a SPI bus, a PCI bus, or a PCIe bus

Each core 1302 and/or, more generally, the microprocessor 1300 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1300 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

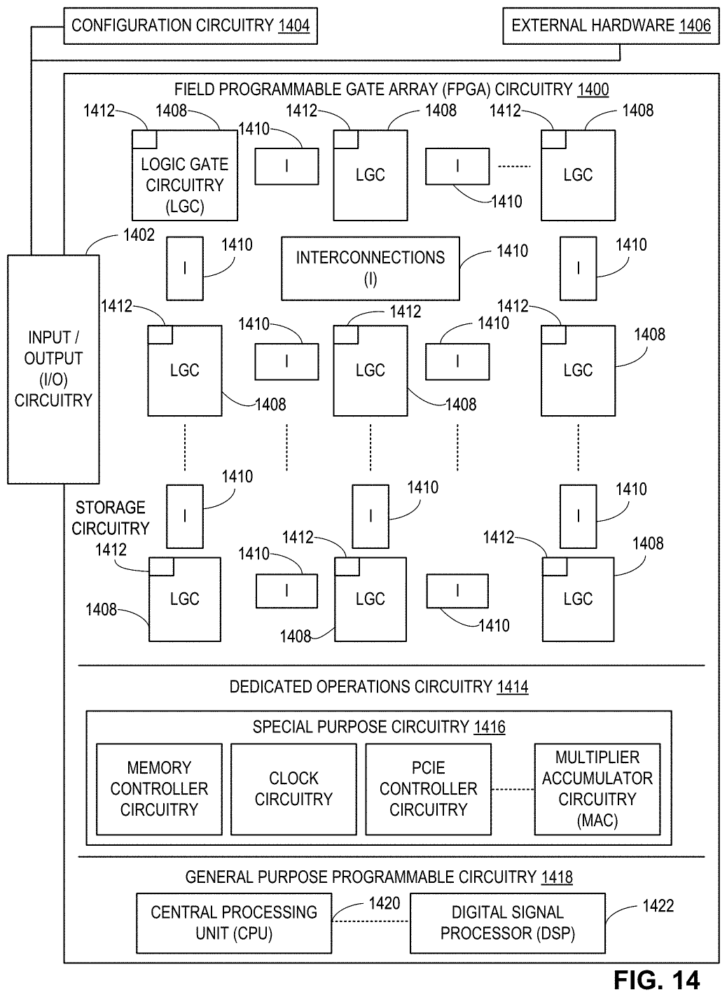

FIG. 14 is a block diagram of another example implementation of the processor circuitry 1212 of FIG. 12. In this example, the processor circuitry 1212 is implemented by FPGA circuitry 1400. For example, the FPGA circuitry 1400 may be implemented by an FPGA. The FPGA circuitry 1400 can be used, for example, to perform operations that could otherwise be performed by the example microprocessor 1300 of FIG. 5 executing corresponding machine readable instructions. However, once configured, the FPGA circuitry 1400 instantiates the machine readable instructions in hardware and, thus, can often execute the operations faster than they could be performed by a general purpose microprocessor executing the corresponding software.

More specifically, in contrast to the microprocessor 1300 of FIG. 13 described above (which is a general purpose device that may be programmed to execute some or all of the machine readable instructions represented by the flowcharts of FIGS. 9-11 but whose interconnections and logic circuitry are fixed once fabricated), the FPGA circuitry 1400 of the example of FIG. 14 includes interconnections and logic circuitry that may be configured and/or interconnected in different ways after fabrication to instantiate, for example, some or all of the machine readable instructions represented by the flowcharts of FIGS. 9-11. In particular, the FPGA circuitry 1400 may be thought of as an array of logic gates, interconnections, and switches. The switches can be programmed to change how the logic gates are interconnected by the interconnections, effectively forming one or more dedicated logic circuits (unless and until the FPGA circuitry 1400 is reprogrammed). The configured logic circuits enable the logic gates to cooperate in different ways to perform different operations on data received by input circuitry. Those operations may correspond to some or all of the software represented by the flowcharts of FIGS. 9-11. As such, the FPGA circuitry 1400 may be structured to effectively instantiate some or all of the machine readable instructions of the flowcharts of FIGS. 9-11 as dedicated logic circuits to perform the operations corresponding to those software instructions in a dedicated manner analogous to an ASIC. Therefore, the FPGA circuitry 1400 may perform the operations corresponding to the some or all of the machine readable instructions of FIGS. 9-11 faster than the general purpose microprocessor can execute the same.

In the example of FIG. 14, the FPGA circuitry 1400 is structured to be programmed (and/or reprogrammed one or more times) by an end user by a hardware description language (HDL) such as Verilog. The FPGA circuitry 1400 of FIG. 14, includes example input/output (I/O) circuitry 1402 to obtain and/or output data to/from example configuration circuitry 1404 and/or external hardware 1406. For example, the configuration circuitry 1404 may be implemented by interface circuitry that may obtain machine readable instructions to configure the FPGA circuitry 1400, or portion(s) thereof. In some such examples, the configuration circuitry 1404 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 1406 may be implemented by external hardware circuitry. For example, the external hardware 1406 may be implemented by the microprocessor 1300 of FIG. 13. The FPGA circuitry 1400 also includes an array of example logic gate circuitry 1408, a plurality of example configurable interconnections 1410, and example storage circuitry 1412. The logic gate circuitry 1408 and the configurable interconnections 1410 are configurable to instantiate one or more operations that may correspond to at least some of the machine readable instructions of FIGS. 9-11 and/or other desired operations. The logic gate circuitry 1408 shown in FIG. 14 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1408 to enable configuration of the electrical structures and/or the logic gates to form circuits to perform desired operations. The logic gate circuitry 1408 may include other electrical structures such as look-up tables (LUTs), registers (e.g., flip-flops or latches), multiplexers, etc.

The configurable interconnections 1410 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1408 to program desired logic circuits.

The storage circuitry 1412 of the illustrated example is structured to store result(s) of the one or more of the operations performed by corresponding logic gates. The storage circuitry 1412 may be implemented by registers or the like. In the illustrated example, the storage circuitry 1412 is distributed amongst the logic gate circuitry 1408 to facilitate access and increase execution speed.

The example FPGA circuitry 1400 of FIG. 14 also includes example Dedicated Operations Circuitry 1414. In this example, the Dedicated Operations Circuitry 1414 includes special purpose circuitry 1416 that may be invoked to implement commonly used functions to avoid the need to program those functions in the field. Examples of such special purpose circuitry 1416 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1400 may also include example general purpose programmable circuitry 1418 such as an example CPU 1420 and/or an example DSP 1422. Other general purpose programmable circuitry 1418 may additionally or alternatively be present such as a GPU, an XPU, etc., that can be programmed to perform other operations.

Although FIGS. 13 and 14 illustrate two example implementations of the processor circuitry 1212 of FIG. 12, many other approaches are contemplated. For example, as mentioned above, modern FPGA circuitry may include an on-board CPU, such as one or more of the example CPU 1420 of FIG. 14. Therefore, the processor circuitry 1212 of FIG. 12 may additionally be implemented by combining the example microprocessor 1300 of FIG. 13 and the example FPGA circuitry 1400 of FIG. 14. In some such hybrid examples, a first portion of the machine readable instructions represented by the flowcharts of FIGS. 9-11 may be executed by one or more of the cores 1302 of FIG. 13, a second portion of the machine readable instructions represented by the flowcharts of FIGS. 9-11 may be executed by the FPGA circuitry 1400 of FIG. 14, and/or a third portion of the machine readable instructions represented by the flowcharts of FIGS. 9-11 may be executed by an ASIC. It should be understood that some or all of the circuitry of FIG. 2 may, thus, be instantiated at the same or different times. Some or all of the circuitry may be instantiated, for example, in one or more threads executing concurrently and/or in series. Moreover, in some examples, some or all of the circuitry of FIG. 2 may be implemented within one or more virtual machines and/or containers executing on the microprocessor.

In some examples, the processor circuitry 1212 of FIG. 12 may be in one or more packages. For example, the microprocessor 1300 of FIG. 13 and/or the FPGA circuitry 1400 of FIG. 14 may be in one or more packages. In some examples, an XPU may be implemented by the processor circuitry 1212 of FIG. 12, which may be in one or more packages. For example, the XPU may include a CPU in one package, a DSP in another package, a GPU in yet another package, and an FPGA in still yet another package.

From the foregoing, it will be appreciated that example systems, methods, apparatus, and articles of manufacture have been disclosed that improve the efficiency of using a computing device by removing dust that accumulates during the operation of fans of the computing device. The efficiency of the computing device is improved as the maintenance mode, which removes the dust is selected in response to a dust buildup rather than continuously running, which reduces wasted electrical power. The efficiency of the computing device is improved as the maintenance mode is quieter than traditional techniques to clean the dust. Disclosed systems, methods, apparatus, and articles of manufacture are accordingly directed to one or more improvement(s) in the operation of a machine such as a computer or other electronic and/or mechanical device.

Example methods, apparatus, systems, and articles of manufacture to remove dust from an electronic device are disclosed herein. Further examples and combinations thereof include the following:

Example 1 includes an apparatus to remove dust from an electronic device. The apparatus includes a fan to rotate in a first direction in a first mode of operation of the electronic device, the first mode of operation corresponding to user operation of the electronic device, at least one memory, machine readable instructions, and processor circuitry to at least one of instantiate or execute the machine readable instructions to determine an operation time of the fan in the first mode of operation, and cause the fan to operate in a second mode of operation based on the operation time exceeding a threshold time, and, wherein, in the second mode of operation, pulsed power is applied to the fan to rotate the fan in a second direction opposite the first direction.

Example 2 includes the apparatus of example 1, wherein the processor circuitry executes the instructions to cause pulsed power to cause rotation of the fan for a first time period, pause the fan for a second time period following the first time period, and cause rotation of the fan for a third time period, the third time period following the second time period, the third time period having the same duration as the first time period.

Example 3 includes the apparatus of example 2, wherein the processor circuitry executes the instructions to determine the first time period, the second time period, and the third time period of the pulsed power based on the operation time of the fan in the first mode of operation.

Example 4 includes the apparatus of any of examples 1 to 3, wherein the processor circuitry executes the instructions to estimate an amount of dust accumulation based on the operation time of the fan in the first mode of operation.

Example 5 includes the apparatus of any of examples 1 to 4, further including a tachometer to determine a number of rotations of the fan, and wherein the processor circuitry executes the instructions to determine an amount of dust accumulation based on a comparison between the number of rotations and a number of expected rotations.

Example 6 includes the apparatus of any of examples 1 to 5, further including a temperature sensor, wherein the processor circuitry executes the instructions to, in response to a first temperature measurement from the temperature sensor, cause the fan to enter the first mode of operation to cool the electronic device, and in response to a second temperature measurement that is less than the first temperature measurement, cause the fan to enter the second mode of operation.

Example 7 includes the apparatus of any of examples 1 to 6, further including a motion sensor, wherein the processor circuitry executes the instructions to prevent activation of the fan when the motion sensor detects that the electronic device is in motion.

Example 8 includes the apparatus of any of examples 1 to 7, wherein the processor circuitry executes the instructions to select a rotation scheme for the fan based on sensor data, the rotation scheme to determine when to apply the pulsed power.

Example 9 includes the apparatus of example 8, further including a global positioning system to determine a location of the electronic device, wherein the processor circuitry executes the instructions to determine when to apply the pulsed power based on a climate determined from the location.

Example 10 includes the apparatus of any of examples 1 to 9, wherein the processor circuitry executes the instructions to monitor fan usage, and to adjust a frequency of activating rotation of the fan based on the fan usage.

Example 11 includes the apparatus of example 10, wherein in response to the determination that the electronic device is in a gaming mode, the processor circuitry is to execute the instructions to increase a frequency of activating the fan in the second mode of operation.

Example 12 includes the apparatus of example 1, further including a network interface to retrieve at least one fan rotation scheme from an online database.

Example 13 includes at least one non-transitory computer readable storage medium comprising instructions that, when executed, cause processor circuitry to at least determine an operation time of a fan in a first mode of operation, the first mode of operation corresponding to user operation of an electronic device, the fan to rotate in a first direction in the first mode of operation, cause the fan to operate in a second mode of operation based on the operation time exceeding a threshold time, and in the second mode of operation, cause pulsed power to be applied to the fan to rotate the fan in a second direction opposite the first direction.

Example 14 includes the computer readable storage medium of example 13, wherein the instructions further cause the processor circuitry to cause rotation of the fan for a first time period, pause the rotation of the fan for a second time period following the first time period, and cause rotation of the fan for a third time period, the third time period following the second time period, the third time period having the same duration as the first time period.

Example 15 includes the computer readable storage medium of example 14, wherein the instructions further cause the processor circuitry to determine the first time period, the second time period, and the third time period of the pulsed power based on the operation time of the fan in the first mode of operation.

Example 16 includes the computer readable storage medium of any of examples 13 to 15, wherein the instructions further cause the processor circuitry to determine a usage mode of the electronic device, and in response to the determination that the usage mode of the electronic device is a gaming mode, the instructions cause the processor circuitry to cause the fan to operate in the second mode of operation.

Example 17 includes a method to remove dust from an electronic device, the method comprising determining an operation time of a fan in a first mode of operation, the first mode of operation corresponding to user operation of the electronic device, the fan to rotate in a first direction in the first mode of operation, causing the fan to operate in a second mode of operation based on the operation time exceeding a threshold time, and in the second mode of operation, applying pulsed power to the fan that causes the fan to rotate in a second direction opposite from the first direction.

Example 18 includes the method of example 17, wherein applying the pulsed power further includes applying a pulsed power to cause rotation of the fan for a first time period, pausing the fan for a second time period following the first time period, and applying the pulsed power for a third time period, the third time period following the second time period, the third time period having the same duration as the first time period.

Example 19 includes the method of any of examples 17 or 18, further including determining an amount of dust accumulation based on a comparison between a number of rotations of the fan and a number of expected rotations.

Example 20 includes the method of any of examples 17 to 19, further including retrieving at least one fan rotation scheme from an online database.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. An apparatus to remove dust from an electronic device, the apparatus comprising:
a fan to rotate in a first direction in a first mode of operation of the electronic device, the first mode of operation corresponding to user operation of the electronic device;
at least one memory;
machine readable instructions; and
processor circuitry to at least one of instantiate or execute the machine readable instructions to:
determine an operation time of the fan in the first mode of operation; and
cause the fan to operate in a second mode of operation based on the operation time exceeding a threshold time, and, wherein, in the second mode of operation, pulsed power is applied to the fan to rotate the fan in a second direction opposite the first direction.

2. The apparatus of claim 1, wherein the processor circuitry executes the instructions to cause pulsed power to be applied to:
cause rotation of the fan for a first time period;
pause the fan for a second time period following the first time period; and
cause rotation of the fan for a third time period, the third time period following the second time period, the third time period having the same duration as the first time period.

3. The apparatus of claim 2, wherein the processor circuitry executes the instructions to determine the first time period, the second time period, and the third time period of the pulsed power based on the operation time of the fan in the first mode of operation.

4. The apparatus of claim 1, wherein the processor circuitry executes the instructions to estimate an amount of dust accumulation based on the operation time of the fan in the first mode of operation.

5. The apparatus of claim 1, further including a tachometer to determine a number of rotations of the fan, and wherein the processor circuitry executes the instructions to determine an amount of dust accumulation based on a comparison between the number of rotations and a number of expected rotations.

6. The apparatus of claim 1, further including a temperature sensor, wherein the processor circuitry executes the instructions to, in response to a first temperature measurement from the temperature sensor, cause the fan to enter the first mode of operation to cool the electronic device, and in response to a second temperature measurement that is less than the first temperature measurement, cause the fan to enter the second mode of operation.

7. The apparatus of claim 1, further including a motion sensor, wherein the processor circuitry executes the instructions to prevent activation of the fan when the motion sensor detects that the electronic device is in motion.

8. The apparatus of claim 1, wherein the processor circuitry executes the instructions to select a rotation scheme for the fan based on sensor data, the rotation scheme to determine when to apply the pulsed power.

9. The apparatus of claim 8, further including a global positioning system to determine a location of the electronic device, wherein the processor circuitry executes the instructions to determine when to apply the pulsed power based on a climate determined from the location.

10. The apparatus of claim 1, wherein the processor circuitry executes the instructions to monitor fan usage, and to adjust a frequency of activating rotation of the fan based on the fan usage.

11. The apparatus of claim 10, wherein in response to the determination that the electronic device is in a gaming mode, the processor circuitry is to execute the instructions to increase a frequency of activating the fan in the second mode of operation.

12. The apparatus of claim 1, further including a network interface to retrieve at least one fan rotation scheme from an online database.

13. At least one non-transitory computer readable storage medium comprising instructions that, when executed, cause processor circuitry to at least:
determine an operation time of a fan in a first mode of operation, the first mode of operation corresponding to user operation of an electronic device, the fan to rotate in a first direction in the first mode of operation;
cause the fan to operate in a second mode of operation based on the operation time exceeding a threshold time; and
in the second mode of operation, cause pulsed power to be applied to the fan to rotate the fan in a second direction opposite the first direction.

14. The computer readable storage medium of claim 13, wherein the instructions further cause the processor circuitry to:
cause rotation of the fan for a first time period;
pause the rotation of the fan for a second time period following the first time period; and
cause rotation of the fan for a third time period, the third time period following the second time period, the third time period having the same duration as the first time period.

15. The computer readable storage medium of claim 14, wherein the instructions further cause the processor circuitry to determine the first time period, the second time period, and the third time period of the pulsed power based on the operation time of the fan in the first mode of operation.

16. The computer readable storage medium of claim 13, wherein the instructions further cause the processor circuitry to determine a usage mode of the electronic device, and in response to determination that the usage mode of the electronic device is a gaming mode, the instructions cause the processor circuitry to cause the fan to operate in the second mode of operation.

17. A method to remove dust from an electronic device, the method comprising:
determining an operation time of a fan in a first mode of operation, the first mode of operation corresponding to user operation of the electronic device, the fan to rotate in a first direction in the first mode of operation;
causing the fan to operate in a second mode of operation based on the operation time exceeding a threshold time; and
in the second mode of operation, applying pulsed power to the fan that causes the fan to rotate in a second direction opposite from the first direction.

18. The method of claim 17, wherein applying the pulsed power further includes:
applying a pulsed power to cause rotation of the fan for a first time period;
pausing the fan for a second time period following the first time period; and
applying the pulsed power for a third time period, the third time period following the second time period, the third time period having the same duration as the first time period.

19. The method of claim 17, further including determining an amount of dust accumulation based on a comparison between a number of rotations of the fan and a number of expected rotations.

20. The method of claim 17, further including retrieving at least one fan rotation scheme from an online database.
